(19) United States
(12) Patent Application Publication
(10) Pub. No.: US 2019/0288175 A1
(43) Pub. Date: Sep. 19, 2019

(54) TAPE TYPE SUPERCONDUCTOR WITH A PLURALITY OF ELONGATED BARRIER STRUCTURES

(71) Applicant: Bruker HTS GmbH, Hanau (DE)

(72) Inventors: Alexander USOSKIN, Hanau (DE); Ulrich BETZ, Alzenau (DE)

(21) Appl. No.: 16/354,348

(22) Filed: Mar. 15, 2019

(30) Foreign Application Priority Data
Mar. 15, 2018 (EP) 18161977.6

(51) Int. Cl. H01L 39/14; H01L 39/24

(52) U.S. Cl. CPC H01L 39/143; H01L 39/2467; H01L 39/248

(57) ABSTRACT

A tape type superconductor (1), extending in longitudinal direction (LD), includes a substrate tape (2), at least one buffer layer (3), a superconductor layer (4), and plural elongated barrier structures (5, 5a, 5b). The superconductor layer has a width W_{SL} in a direction (WD) that is perpendicular to the longitudinal direction and runs parallel to a flat side (8) of the substrate tape. The tape type superconductor has a longitudinal length L_{TTS} t, and the elongated barrier structures are oriented in parallel with the longitudinal direction. A respective barrier structure has a longitudinal length L_{BS}, with L_{BS}≥0.20*W_{SL} and L_{BS}≤0.20*L_{TTS}. The barrier structures are distributed longitudinally, are located at least partially in the superconductor layer, and impede a superconducting current flow in width direction across a respective barrier structure. This tape type superconductor achieves high critical currents simply and over extended tape lengths with suppressed magnetization.

### CROSS REFERENCE TO RELATED APPLICATIONS

This application claims foreign priority under 35 U.S.C. § 119(a)-(d) to European Application No. 18 161 977.6 filed on Mar. 15, 2018, the entire contents of which are hereby incorporated into the present application by reference.

### FIELD OF INVENTION

The invention relates to a tape type superconductor, extending along a longitudinal direction, comprising
a substrate tape,
at least one buffer layer, and
a superconductor layer,
   said superconductor layer having a width W_{SL} in a width direction, with the width direction being perpendicular to the longitudinal direction and being parallel to a substrate tape flat side,
   and said tape type superconductor having a length L_{TTS} in longitudinal direction.

### BACKGROUND

Such a tape type superconductor is known, e.g., from US 2007/0191202 A1.

Superconductors can be used to carry an electric current at practically no ohmic losses, for example in order to produce high strength magnetic fields in superconducting magnet coils, or simply to transport the current from a source to a consumer. Superconductor materials have to be cooled to cryogenic temperatures in order to assume superconductivity. While low temperature superconductors (=LTS) such as NbTi are in general metallic and therefore can be prepared easily for example as drawn wires, high temperature superconductors (=HTS) such as YBCO are in general ceramic and therefore are often prepared as tape type superconductors to compensate for the brittle characteristics of the ceramic HTS.

Tape type superconductors typically comprise a substrate of preferably flexible material such as steel, covered with at least one buffer layer and a superconductor layer. Manufacturing of a HTS coated tape is for example described in EP 2 490 273 A1.

Tape type superconductors are difficult to prepare at high quality, in particular over an extended length. In particular, local defects in the superconductor layer may deteriorate the achievable critical current. When transporting AC currents, significant AC losses due to eddy currents may occur. More generally, induced superconducting closed loop shielding currents store energy in the tape type superconductor, and generate magnetic moments. The magnetization may decrease the conductor stability, i.e. the risk of a sudden loss of superconductivity (“quench”) may rise. Further, magnetization may lead to field oscillations, deteriorating measurements such as NMR measurements performed with a magnetic coil using the tape type superconductor.

In order to reduce AC losses, EP 2 144 255 A1 proposes a superconducting cable having a channel for cooling liquid and a tubular support structure, wherein high Tc superconductors are arranged in two layers using different high Tc materials, and having normal-conducting interruptions in the high Tc conductors of the outer layer.

US 2007/0191202 A1 proposes a superconducting tape with a segmented HTS layer. Disruptive strips are formed in one of the tape substrate, a buffer layer, and a superconducting layer, and create parallel discontinuities in the superconductor layer, which reduces AC losses.

In this design, the superconductor layer is formed of parallel superconducting filaments. While this works well for relatively short tape lengths, for more extended tape lengths local defects in the superconductor filaments become more probable, which can make an affected superconducting filament useless. Therefore, good critical currents are difficult to achieve for more extended tape lengths.

U.S. Pat. No. 9,786,415 B2 proposes a high temperature superconductor tape including a plurality of superconducting filaments, to improve a transverse tensile strength. The filaments may be produced by removing portions of a superconductive layer.

US 2017/0287599 A1 proposes a superconducting wire with a base material, an intermediate layer, and an oxide superconducting layer. The intermediate layer comprises non-orientation regions extending in a longitudinal direction of the base material, which lead to non-orientation regions in the oxide superconducting layer, too, which have no superconducting characteristics or a significantly lower critical current.

DE 10 2009 038 920 A1 proposes a multifilament conductor, wherein superconducting filaments are inclined with respect to a longitudinal direction of the multifilament conductor. The filaments are wound about a substrate. The multifilament conductor has decreased electric losses, and minimizes inductance of currents in external alternating fields. In one embodiment, bridges are provided between neighbouring wound filaments.

The filaments wound about the substrate are difficult to produce and come along with currents flowing in a screw like fashion, what generates magnetic fields along the screw axis, which are generally undesired. Further, using the bridges between neighbouring wound filaments may require current flow against the overall flow direction, which deteriorates the achievable magnetic field strength.

### SUMMARY

It is an object of the invention to present a tape type superconductor, with which high critical currents may be achieved in a simple way over extended tape lengths with suppressed magnetization.

This object is achieved, in accordance with one formulation of the invention, by a tape type superconductor as introduced above,

characterized in
that the tape type superconductor comprises a plurality of elongated barrier structures which are oriented in parallel with the longitudinal direction,
wherein a respective barrier structure has a length L_{BS} in longitudinal direction,
with L_{BS}≥0.20*W_{SL} and L_{BS}≤0.20*L_{TTS},
that the barrier structures are arranged distributed along the longitudinal direction, and that the barrier structures are located at least partially in the superconductor layer and impede a superconducting current flow in width direction across a respective barrier structure.

The inventive tape type superconductor permits high electrical currents to be transported along the longitudinal direction (or tape direction) superconductively. In particular, the barrier structures extending in parallel to the longitudinal direction do not hinder the transport of the electrical current in this longitudinal direction in the superconductor layer. Further note that no currents turned around the substrate tape are established.

Further, less energy is stored in the form of magnetization. The tape type superconductor is more stable against quenches, and also field oscillations (that might deteriorate NMR measurements, for example) are reduced. The reduction in magnetization is achieved in spite of the limited length of the barrier structures in longitudinal direction and their arrangement distributed in longitudinal direction.

In order to have a good protection against shielding currents, the invention proposes a minimum length L_{BS} of the barrier structures as compared to the (overall) superconductor layer width W_{SL}, with L_{BS}≥0.20 W_{SL}.

In accordance with the invention, the barrier structures are significantly shorter than the length L_{TTS} of the tape type superconductor, with L_{BS}≤0.20 L_{TTS}. This allows a circumvention of possible local defects in the superconductor layer. The superconducting current may, if needed, flow in width direction (“transverse flow”) in front of and behind a barrier structure, and thus switch to an area in width direction not affected by a local defect in the superconductor layer. The switching of the superconductive current in width direction is easy and does not require any effective back currents, since the barrier structures extend in parallel with the longitudinal direction.

The electric current flow in width direction may be controlled by a non-linear conductivity of intermediate regions of superconductor layer material which precede and follow barrier structures in width direction; the intermediate regions typically form narrow gaps between each two barrier structures which are at the same position in width direction and which are subsequent in longitudinal direction. The intermediate regions form superconductive links between areas of the superconductor layer which are adjacent in width direction. These superconductive links are relatively weak, though. The superconductive links may easily be overloaded with shielding currents which are responsible for a coupling of said adjacent areas. Therefore, in high magnetic fields, the intermediate regions tend to be at normally conducting state, and due to this normally conducting state, shielding currents responsible for coupling of said adjacent areas are suppressed. However, if a non-superconductive defect is present in one of said adjacent areas, the coupling shielding currents are at a lower level in the vicinity of the defect. Therefore, the neighboring intermediate regions may carry additional current helping in bypassing the defect. This behavior results in a self-adjusting cross-coupling between said adjacent areas of the superconductor film, and may allow for a further increase in the usable length of the inventive tape-type superconductor.

Further, the barrier structures are simple to produce, in particular over long lengths, since they are in parallel with the extension direction. In the most simple case, the tape type superconductor may be treated during a winding the tape in order to establish the barrier structures, with a tool or tools located at a constant position in width direction.

Note that the substrate tape of an inventive tape type superconductor is in general only covered with a superconductor layer on one of its flat sides. Typically, there is also a metallic coating covering the superconductor layer (and also the barrier structures). The substrate tape is typically polished before depositing a buffer layer and the superconductor layer.

Note that typically L_{BS}≤(10⁻³)*L_{TTS} or even L_{BS}≤(10⁻⁵)*L_{TTS}, and further typically L_{TTS}≥10 m or even L_{TTS}≥100 m. The width W_{SL} of the superconducting layer (and also the width of the tape type superconductor in general) is typically from 1.5 mm to 2 cm, and often from 2.5 mm to 1.0 cm. A typical length L_{BS} is from 2.0 mm to 2.5 cm, and often from 3.0 mm to 1.5 mm. In general, the barrier structures are also arranged distributed in width direction. The arrangement of barrier structures is preferably non-periodic along the longitudinal direction (or tape direction). However, a periodic arrangement of the barrier structures is also possible, in particular with a period P much longer than the (average) length L_{BS}, such as P≥5*L_{BS}.

Typically, all barrier structures have a uniform length L_{BS}. However, it is also possible to have a distribution of barrier structure lengths in the tape type superconductor. Structures having dimensions not covered by the defined requirements (see above) are not considered as barrier structures in the sense of the present invention.

### Various Embodiments of the Invention

In a preferred embodiment of the inventive tape type superconductor, a respective barrier structure stretches across the complete height H_{SL} of a the superconductor layer in a height direction, with the height direction being perpendicular to the longitudinal direction and being perpendicular to the substrate tape flat side. This provides a maximum impediment for a superconducting current in width direction at the barrier structure, and thus optimum protection against undesired shielding currents or magnetization, and is simple to produce.

Particularly preferred is an embodiment wherein the barrier structures are non-superconducting or exhibit a critical current density j_{c}^{BS} in width direction which is less than 1/100 of a critical current density j_{c}^{SL} in width direction of a superconducting material of the superconductor layer. This makes sure that superconductive shielding currents across the barrier structures can be excluded or at least kept significantly weaker than a (regular) longitudinal superconductive current.

In an advantageous embodiment, the barrier structures are spaces filled with a non-superconducting material of a different chemical composition as compared to the superconducting material of the superconductor layer, in particular wherein the spaces are filled with a non-superconducting metal. Establishing a different chemical structure in the spaces is a simple and highly reliable measure for implementing a barrier structure. Typically, the spaces are first made by removing material from a (closed) superconductor layer, and then the resultant gaps are filled with the non-superconducting material. Metals are particularly simple to use for the latter purpose. Alternatively, a chemical composition can be changed locally e.g. by ion bombardment. This embodiment typically includes a post treatment of a (continuous) superconductor layer.

In an alternative embodiment, the barrier structures have the same chemical composition as the superconducting material of the superconductor layer, but exhibit deviations from the phase composition and/or exhibit disturbances in the crystalline structure as compared to the superconducting material of the superconductor layer. The barrier structures are typically established by treating the substrate tape or a buffer layer at locations where barrier structures are desired (“disturbance pattern”), before depositing the superconductor layer. The superconducting material only assumes the superconducting phase away from the disturbance pattern. then no post treatment of a superconductor layer is needed. However, it is also possible to alter the chemical (or elemental) composition e.g. by a local heat treatment.

In a preferred embodiment, at least 80%, preferably at least 90%, of the length L_{TTS} of the tape type superconductor is overlapped by barrier structures. In this way, a high level of protection against undesired shielding currents and magnetization in the superconductor layer can be achieved.

Particularly preferred is a further development of this embodiment, wherein 100% of the length L_{TTS} of the tape type superconductor is overlapped by barrier structures. This establishes an even better protection against undesired shielding currents and magnetization.

In a preferred embodiment, at least 80%, preferably at least 90%, of the length L_{TTS} of the tape type superconductor is overlapped by at least n barrier structures which are sequent in width direction, with n≥2. Preferably, 100% of the length L_{TTS} of the tape type superconductor is overlapped by at least n barrier structures which are sequent in width direction, with n≥2. With more overlapping barrier structures, a finer limitation of spaces in width direction for shielding currents may be achieved, what helps to reduce undesired magnetization further.

In a particularly preferred embodiment for an average barrier density ABD, which is defined as a local barrier density of the tape type superconductor averaged along the complete length L_{TTS}, with the local barrier density being the number of barrier structures intersected by a cross section of the tape type superconductor perpendicular to the longitudinal direction at a local position in longitudinal direction, the following applies

ABD≥0.80,

preferably ABD≥1.0,
most preferably ABD≥2.0. With a high average barrier density, a high level of protection against shielding currents or magnetization, respectively, can be achieved. Note that often ABD>2.0 also applies. Note further that often ABD≤4 applies.

A preferred further development of this embodiment provides that
ABD≤2.5 and W_{SL}/(2*ABD)≤L_{BS}, and/or
ABD≤250 and L_{BS}≤(50/ABD)*W_{SL}, and/or
ABD≤5 and W_{SL}/ABD≤L_{BS}, and/or
ABS≤125 and L_{BS}≤(25/ABD)*W_{SL}. With these parameters, the density of barrier structures is typically adequate for a good protection against undesired magnetization, and for not being prone to local defects in the superconductor layer. Also preferred is W_{SL}/(ABD+1)≤L_{BS}, for ABD≤4.

In another advantageous further development, the barrier structures are arranged distributed over at least m different positions in width direction,

with m>2*ABD or m>3*ABD,
in particular wherein on average over the length L_{TTS}, the barrier structures are basically equally distributed over the at least m different positions in width direction. In this case, the barrier structures may be put at a variety of different positions, in particular more different positions than necessary for achieving the given average barrier density ABD. In this way, the barrier structure distribution may be more versatile, and in particular random patterns may be established easily, which are less prone to quenches and undesired magnetic field components than regular or periodic patterns. Preferably, the at least m different positions are basically equally distributed in width direction.

In a preferred embodiment, 0.25*W_{SL}≤L_{BS} and/or L_{BS}≤25*W_{SL},

preferably with 0.5*W_{SL}≤L_{BS} and/or L_{BS}≤12.5*W_{SL}. Often also L_{BS}≤5*W_{SL} applies. With these parameters again, the dimensions of barrier structures are typically adequate for a good protection against undesired magnetization, and for not being prone to local defects in the superconductor layer.

Preferred is further an embodiment wherein the barrier structures have an aspect ratio AR_{BS}=L_{BS}/W_{BS}, with AR_{BS}≥10, preferably AR_{BS}≥20, with W_{BS}: width of a respective barrier structure in width direction. Typically there is also AR_{BS}≤500, in particular AR_{BS}≤100. Note that W_{BS} is typically about 25 μm through 250 μm. These dimensions are both easy to produce and offer a high protection against undesired increased shielding currents or magnetization, respectively.

In a preferred embodiment, the superconducting material of the superconductor layer is a high temperature superconductor, in particular REBCO or BiSCCO or MgB₂. On the inventive tape type superconductor, in particular with a flexible substrate tape, these brittle materials may be handled safely and used for typical applications such as superconducting coils, for example as magnets in NMR (nuclear magnetic resonance) apparatus.

Also preferred is an embodiment wherein the substrate tape is made of metal, in particular stainless steel or Hastelloy. Metal substrate tapes are safe to handle, in particular for winding coils. Alternatively, the substrate tape can be made, for example, of a ceramic material. Note that in general, the substrate tape (and the tape type superconductor as a whole) is preferably flexible.

### Methods for Producing Inventive Tape Type Superconductors

Also within the scope of the present invention is a method for producing an inventive tape type superconductor, wherein the barrier structures are spaces filled with a non-superconducting material of a different chemical composition as compared to the superconducting material of the superconductor layer, characterized in that
at least one continuous buffer layer is deposited on the substrate tape,
a continuous superconductor layer is deposited on the at least one continuous buffer layer,
at locations intended for barrier structures, the superconducting material of the superconductor layer is locally removed, in particular by laser etching, thus forming grooves reaching at least to the at least one buffer layer,
and the grooves are filled with the non-superconducting material of a different chemical composition as compared to the superconducting material of the superconductor layer. This is a simple and highly reliable method for implementing the barrier structures. The non-superconducting material may be a metal, for example a metal also used for a protective layer or shunt layer.

Alternatively, in accordance with the invention, there is a method for producing an inventive tape type superconductor wherein the barrier structures are spaces filled with a non-superconducting material of a different chemical composition as compared to the superconducting material of the superconductor layer, characterized in that
at least one continuous buffer layer is deposited on the substrate tape,
a continuous superconductor layer is deposited on the at least one continuous buffer layer,
at locations intended for barrier structures, the superconducting material of the superconductor layer is locally converted into the non-superconducting material of a different chemical composition as compared to the superconducting material of the superconductor layer, in particular by ion bombardment. This method produces less dirt in general, since no removal of material is necessary, but typically takes long time for thorough material conversion.

Further within the scope of the present invention is a method for producing an inventive tape type superconductor, wherein the barrier structures have the same chemical composition as the superconducting material of the superconductor layer, but exhibit deviations from the phase composition and/or exhibit disturbances in the crystalline structure as compared to the superconducting material of the superconductor layer, characterized in that
at locations intended for barrier structures,
   a) a surface of a buffer layer deposited on the substrate tape is locally disturbed, in particular by scratching or laser etching, thus forming a disturbance pattern, or
   b) a surface of a substrate tape is locally disturbed, in particular by scratching or laser etching, thus forming a disturbance pattern, and a buffer layer is deposited on the substrate tape,
and material is deposited on the buffer layer, wherein the superconducting material of the superconductor layer forms everywhere on the buffer layer but on the disturbance pattern. In this method, no post-treatment of the superconductor layer is necessary for establishing the barrier structures, what reduces the risk of damages (such as introducing defects, or lowering the critical current density in general) into the superconductor layer. Note that disturbing the surface typically occurs via implementing an increased surface roughness, but may also include implementing a surface inclination (e.g. >2°) as compared to the undisturbed surface.

Alternatively, in accordance with the invention, there is a method for producing an inventive tape type superconductor, wherein the barrier structures have the same chemical composition as the superconducting material of the superconductor layer, but exhibit deviations from the phase composition and/or exhibit disturbances in the crystalline structure as compared to the superconducting material of the superconductor layer, characterized in that
at least one continuous buffer layer is deposited on the substrate tape,
a continuous superconductor layer is deposited on the at least one continuous buffer layer,
at locations intended for barrier structures, the superconducting material of the superconductor layer is locally treated, imposing a new phase composition and/or disturbances in the crystalline structure without changing the chemical composition, in particular by local heating. This method is particularly simple during deposition, but requires very careful local treatment in order to reliably establish a non-superconducting material (or a superconducting material with significantly worse critical current than the superconducting material of the superconductor layer) by the treatment in the desired design.

Further advantages can be extracted from the description and the enclosed drawing. The features mentioned above and below can be used in accordance with the invention either individually or collectively in any combination. The embodiments mentioned are not to be understood as exhaustive enumeration but rather have exemplary character for the description of the invention.

### BRIEF DESCRIPTION OF THE DRAWINGS

The invention is shown in the drawing.

FIG. 1A shows a schematic top view of a first embodiment of an inventive tape type superconductor, with barrier structures at one width position, subsequent along the longitudinal direction;

FIG. 1B a schematic cross-section of the superconductor of FIG. 1A at plane IB;

FIG. 1C a schematic cross-section of the superconductor of FIG. 1A at plane IC;

FIG. 2A shows a schematic top view of a second embodiment of an inventive tape type superconductor, with barrier structures at two width positions, subsequent along the longitudinal direction;

FIG. 2B a schematic cross-section of the superconductor of FIG. 2A at plane IIB;

FIG. 2C a schematic cross-section of the superconductor of FIG. 2A at plane ITC;

FIG. 2D a schematic cross-section of the superconductor of FIG. 2A at plane IID;

FIG. 3 shows a schematic top view of a third embodiment of an inventive tape type superconductor, with barrier structures at three width positions, with periodically arranged barrier structures;

FIG. 4 shows a schematic top view of a fourth embodiment of an inventive tape type superconductor, with barrier structures at three width positions, with barrier structures of variable length arranged in a random pattern;

FIG. 5 shows a schematic top view of a fifth embodiment of an inventive tape type superconductor, with barrier structures at five width positions, with barrier structures of fixed length arranged in a random pattern;

FIG. 6A-6F show schematically, through six cross-sections, a sequence illustrating a first variant of a method for producing an inventive tape type superconductor, including a laser etching of grooves in a superconductor layer;

FIG. 7A-7C show schematically, through three cross-sections, a sequence illustrating a second variant of a method for producing an inventive tape type superconductor, including an ion bombardment of regions of a superconductor layer;

FIG. 8A-8D show schematically, through four cross-sections, a sequence illustrating a third variant of a method for producing an inventive tape type superconductor, including scratching of a buffer layer;

FIG. 9A-9C show schematically, through three cross-sections, a sequence illustrating a fourth variant of a method for producing an inventive tape type superconductor, including local heating of regions of a superconductor layer.

### DETAILED DESCRIPTION

It should be noted that the figures are schematic in nature, and some features may be shown in an exaggerated or understated way, in order to show particular features of an inventive tape type superconductor or an inventive production method more clearly.

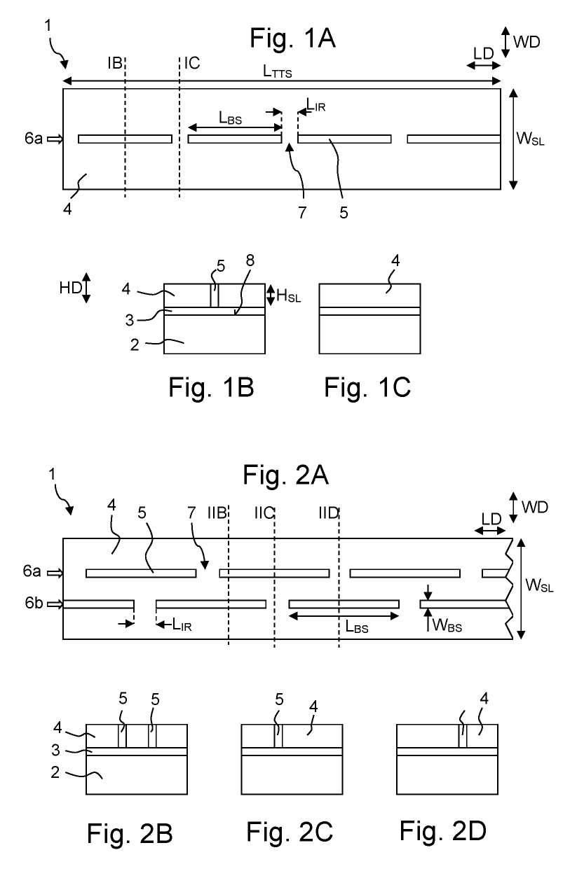

FIG. 1A shows a first embodiment of an inventive tape type superconductor 1 in a schematic top view. FIGS. 1B and 1C illustrate cross-sectional views of the tape type superconductor 1 perpendicular to the longitudinal direction LD at positions of planes IB and IC.

The tape type superconductor 1 comprises a substrate tape 2, which is flexible so it can be wound for example into a solenoid type coil, further at least one buffer layer 3 deposited on a flat side 8 of the substrate tape 2, and a superconductor layer 4 deposited on top of the at least one buffer layer 3. Typically, the superconductor layer 4 is further covered with a metallic protection layer or shunt layer (not shown), for example made of a noble metal such as silver or made of copper. The superconductor layer 4 is made of a superconducting material, typically a high temperature superconductor material of ceramic type such as YBCO.

Further, the tape type superconductor 1 includes a plurality of barrier structures 5 extending in parallel (within the manufacturing accuracy) to the longitudinal direction LD. The barrier structures 5 extend over the complete height H_{SL} of the superconductor layer 4 in a height direction HD (which runs perpendicular to the flat side 8). The barrier structures 5 are filled with a material that is non-superconducting, such as a metal, or filled with a material with significantly worse superconducting characteristics as compared to the superconducting material of the superconductor layer 4, for example with a critical current density lower by a factor of more than 100 (at the same temperature and magnetic field strength during operation). Note that preferably, the material of the barrier structures 5 is normally conductive, with an electrical conductivity corresponding to the conductivity of copper or better (at operating temperature, such as at 4.2 K). The barrier structures 5 are separate from each other, such that in general, each barrier structure 5 is surrounded by superconducting material of the superconductor layer 4 in width direction WD and longitudinal direction LD (with the exception of end faces of barrier structures 5 at an end of the tape type superconductor 1, see here right end in FIG. 1A).

The tape type superconductor 1 is intended for transporting an electric current superconductingly along the longitudinal direction LD.

In the example shown, the barrier structures 5 have a uniform length L_{BS} in longitudinal direction LD, the overall tape type superconductor 1 has a length L_{TTS} in longitudinal direction LD, and the superconductor layer 4 has a constant width W_{SL} (which is here identical to a width of the tape type superconductor 1 in general) in width direction WD. The barrier structures 5 are arranged subsequent in longitudinal direction LD, and are all arranged at the same position 6a (m=1) in width direction, such that the position 6a is in the middle of the tape type superconductor 1 with respect to the width direction WD. Between each two neighboring barrier structures 5 in the sequence, there is an intermediate region 7 belonging to the superconductive layer 4, and therefore with the superconductive characteristics of the superconducting material of the superconductor layer 4. At the intermediate regions 7, a superconducting current may flow between an (in FIG. 1A) upper part and a lower part of the superconductor layer 4. The intermediate regions 7 here have a uniform length of L_{IR} in longitudinal direction LD. In other words, the barrier structures 5 here form a regular “dashed line” pattern in the superconductor layer 4.

In the example shown, the following roughly applies:

a) L_{BS}=0.20*L_{TTS}; note that typically L_{TTS} is much longer than shown in the example, so often L_{BS}≤0.001*L_{TTS}, for example;
b) L_{BS}=0.92*W_{SL};
c) L_{IR}=0.17*L_{BS}; note that this means here that about 86% of the entire length L_{TTS} is overlapped by barrier structures 5, and an average barrier density ABD is about 0.86 in this case.

The barrier structures 5 separate the superconductor layer 4 into an (in FIG. 1A) upper part and a lower part where areas for particular shielding currents are reduced. When m>1, they are even more reduced with consequent suppression of shielding currents and related magnetization. Thus, in case shown in FIG. 1A, the invention provides a decoupling of regions in the superconductor layer 4 at opposing sides of a respective barrier structure 5 (“adjacent areas”). On the other hand, at the intermediate regions 7 a current exchange (i.e. partial coupling) may take place. This coupling represents a non-linear effect which allows more homogeneous distribution of the entire transport current in the entire cross-section (width) of the tape.

In the following, further embodiments of inventive tape type superconductors 1 are explained, and only the major differences with respect to the embodiment shown in FIGS. 1A-1C are discussed in more detail.

FIG. 2A in top view and FIGS. 2B, 2C and 2D in cross-sectional views at the positions of planes IIB, IIC and IID show a second embodiment of an inventive tape type superconductor 1. Note that the end at the right hand side of the tape type superconductor 1 is shown abbreviated in FIG. 2A here.

In this embodiment, barrier structures 5 of uniform length L_{BS} are located at two positions 6a, 6b (m=2) in width direction WD; note that in general, embodiments wherein the barrier structures 5 are distributed over a plurality of positions in width direction WD (i.e. m≥2) are generally preferred, so shielding currents may be more limited in space in width direction WD, in order to achieve a lower magnetization. At each position 6a, 6b, barrier structures 5 are arranged subsequent in longitudinal direction LD, with intermediate regions 7 of uniform length L_{IR} between barrier structures 5 neighboring in longitudinal direction LD.

The intermediate regions 7 of positions 6a and 6b are displaced in longitudinal direction such that they do not mutually overlap. Seen the other way, the barrier structures 5 of positions 6a and 6b are displaced in longitudinal direction such that they do mutually overlap, here at both ends. As a result, all of the length L_{TTS}, i.e. 100%, are overlapped by at least one barrier structure 5. FIGS. 2C, 2D illustrate the situations with one barrier structure 5 in cross-section, which here applies over about 35% of the length L_{TTS}. FIG. 2B illustrates the situation with two barrier structures 5 in cross-section, which here applies about 65% of the length L_{TTS}. This results in an average barrier density ABD of (0.35*1)+(0.65*2)=1.59 for the illustrated tape type superconductor 1. In the example shown, approximately L_{BS}=1.07*W_{SL} and further L_{IR}=0.21*L_{BS} applies.

In general it is preferred that

L_{IR}≥0.25*W_{SL}/(m+1) and/or L_{IR}≤4*W_{SL}/(m+1),
preferably L_{IR}≥0.5*W_{SL}/(m+1) and/or L_{IR}≤2*W_{SL}/(m+1), with m: number of positions in width direction over which the barrier structures 5 are distributed. Often L_{IR}≤W_{SL} is also preferred, and often L_{IR}≤W_{SL}/4 or even L_{IR}≤W_{SL}/10 also applies.

The positions 6a, 6b are basically equally distributed over the width W_{SL} of the superconductor layer 4 or of the tape type superconductor 1, respectively. The barrier structures 5 have an aspect ratio AR_{BS}=L_{BS}/W_{BS}, with W_{BS} being the width of the barrier structure 5 in width direction WD, and with here approximately AR_{BS}=14; note that in general, aspect ratios AR_{BS} of 10 or more, or even 20 or more are preferred.

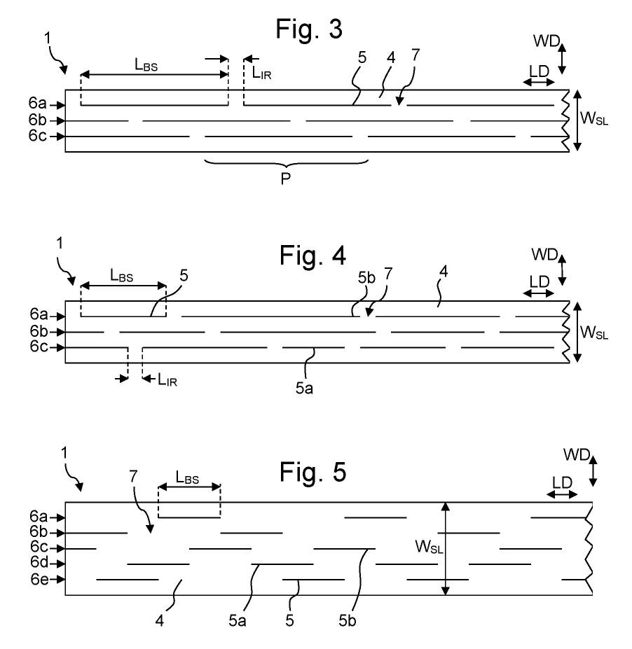

FIG. 3 illustrates a third embodiment of an inventive tape type superconductor 1, wherein the barrier structures 5 having a uniform length L_{BS} are distributed equally over three positions 6a, 6b, 6c (i.e. m=3) in width direction WD. Again, the barrier structures 5 at each position 6a-6c are arranged one behind the other, separated by intermediate regions 7 of uniform length L_{IR}.

In the example shown, the following approximately applies:

a) L_{BS}=2.38*W_{SL};
b) L_{IR}=0.11*L_{BS}; since the intermediate regions 7 do not overlap, this results in an average barrier density ABD of [3*0.11*2+(1.11−3*0.11)*3]/(1.11)=2.70.

In this embodiment, the barrier structures 5 are arranged periodically with respect to the longitudinal direction LD, here with a period P corresponding to the entirety of one barrier structure 5 and one adjacent intermediate region 7, and here with approximately P=2.63*W_{SL}.

FIG. 4 illustrates in a fourth embodiment a tape type superconductor 1 similar to the embodiment shown in FIG. 3, so only the major differences are discussed.

In the fourth embodiment, the barrier structures 5 have a variable length L_{BS}. However, intermediate regions 7 between barrier structures subsequent in longitudinal direction at the same position 6a-6c have a uniform length L_{IR} in longitudinal direction LD.

In the example shown, the barrier structure 5a has the shortest length L_{BS}^{short}, for which applies here approximately L_{BS}^{short}=1.0*W_{SL}, and the barrier structure 5b has the longest length L_{BS}^{long}; for which applies here approximately L_{BS}^{long}=2.9*W_{SL}. The lengths L_{BS} of all barrier structures 5 are randomly distributed between L_{BS}^{short} and L_{BS}^{long}, and said barrier structures 5 are randomly arranged at the positions 6a-6c in random sequences.

However, as a border condition, an overlap of intermediate regions 7 should not be allowed for neighboring positions 6a-6c, and preferably should not be allowed for any positions 6a-6c (as shown here). Please note that in case of long enough (average) lengths L_{BS} as compared to the length L_{IR}, for example for (average) L_{BS}≥50*L_{IR}, an overlap of intermediate regions 7 for neighboring positions 6a-6c in random arrangements becomes so rare that it does not need to be considered any more.

A random arrangement of barrier structures 5 along the tape type superconductor 1, as shown for example in FIG. 4 (see above) and FIG. 5 (see below), may help to prevent congeneric behavior at different sections of the tape type superconductor 1 which may add up or cause self-enforcing effects, in particular resulting in a quench or the built up of undesired magnetic field components. This is particularly true if the tape type superconductor 1 is wound in such a way that sections of the tape type superconductor 1 are arranged neighboring in width direction WD and/or neighboring in a direction perpendicular to the tape plane (i.e. one above the other section).

FIG. 5 illustrates in a top view a fifth embodiment of the inventive tape type superconductor 1.

In this embodiment, the barrier structures 5 have a uniform length L_{BS} in longitudinal direction LD and are distributed equally over five positions 6a-6e (i.e. m=5) in width direction WD, with said positions 6a-6e also being equally distributed along the width direction WD.

In the example shown, each barrier structure 5 has an overlap with two other barrier structures 5a, 5b, with each of the other barrier structures 5a, 5b overlapping with half of the length of said barrier structure 5 at the end and at the front, respectively. As a result, an average barrier density ABD=2 is established.

Along the longitudinal direction LD, for a given barrier structure 5, the position 6a-6e at which the next overlapping barrier structure 5b is located is randomly chosen from the positions which are unequal to the positions of said barrier structure 5 and the previous barrier structure 5a. For example, for said barrier structure 5 marked in FIG. 5 at position 6e, which has a previous barrier structure 5a at position 6d, the next barrier structure 5b may be chosen among positions 6a, 6b and 6c, and in the example shown, the next barrier structure 5b happens to be located at position 6c.

As a consequence of the random arrangement of barrier structures 5, barrier structures 5 at the same width position 6a-6e and subsequent in longitudinal direction LD are separated by intermediate regions 7, with the intermediate regions 7 having random extensions in longitudinal direction.

When the number m of available positions 6a-6e is relatively big as compared to ABD, for example with m>2*ABD or with m≥(ABD+2), and here with m=2.5*ABD or m=ABD+3, respectively, a particularly large variety of possible (random) arrangements of the barrier structures 5 is available. In this case, congeneric behavior and self-enforcing effects are even less likely.

In the illustrated example, approximately L_{BS}=0.67*W_{SL} applies; note that for relatively big m as compared to ABD, relatively short lengths L_{BS} of the barrier structures 5 are preferred, for example with L_{BS}≤2*W_{SL}/(ABS+1).

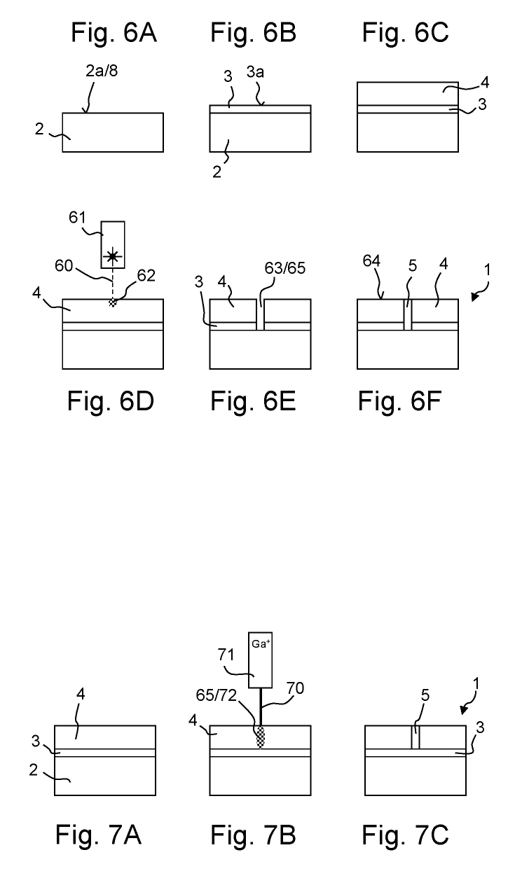

FIGS. 6A-6F illustrate a first variant of a method for producing an inventive tape type superconductor; in each case, cross-sections perpendicular to the longitudinal direction are shown.

The method starts with a substrate tape 2, for example a steel substrate or a Hastelloy substrate, polished at its surface 2a of the flat side 8, see FIG. 6A. On its surface 2a, at least one continuous buffer layer 3 is deposited then, see FIG. 6B. On the surface 3a of the (uppermost) buffer layer 3, a continuous superconductor layer 4 is deposited, see FIG. 6C.

Then at locations intended for barrier structures, a laser beam 60 originating from a laser device 61 is applied, compare FIG. 6D. The laser beam 60 strongly heats and etches away superconducting material close to the laser spot 62, what results in a groove 63 in the superconductor layer 4, and here also in the buffer layer 3, compare FIG. 6E. The space 65 of the groove 63 is then filled with material, here with a non-superconducting metal such as gold or silver, resulting in a barrier structure 5, compare FIG. 6F. Then the tape type superconductor 1 is finished. Note that typically a protection layer or shunt layer is further deposited on the combined surface 64 of the superconductor layer 4 and the barrier structure 5 (not shown).

Please note that in FIG. 6F only one barrier structure 5 is included in the cross-section for simplicity, but the tape type superconductor 1 may include other numbers of barrier structures 5 or other arrangements than shown.

In the second variant of a method for producing a tape type superconductor shown in FIG. 7A-7C, first a semi-finished product with a substrate tape 2, at least one continuous buffer layer 3 and a continuous superconductor layer 4, here of YBCO, is produced (see also FIGS. 6A-6C above), compare FIG. 7A. Then at locations intended for barrier structures, a beam 70 of gallium ions (Ga⁺) is directed, with the gallium ions being provided by an ion gun 71, compare FIG. 7B. Note that said ion bombardment should be done under vacuum conditions. In a region 72, the material of the superconductor layer 4 is enriched with gallium, thus locally changing the chemical composition in the corresponding space 65. In the region 72, the superconducting characteristics get lost, what results in a barrier structure 5 of non-superconducting material in the tape type superconductor 1, compare FIG. 7C.

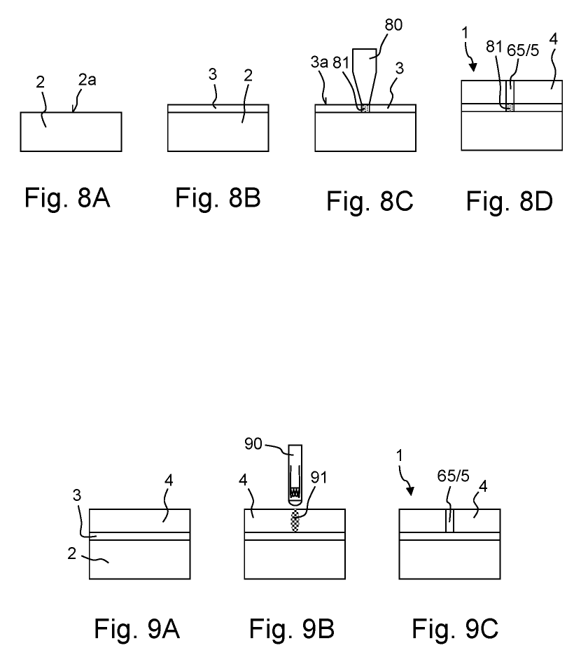

FIGS. 8A-8D illustrate a third variant of a method for producing a tape type superconductor.

On a polished surface 2a of a substrate tape 2, see FIG. 8A, a continuous buffer layer 3 is deposited, see FIG. 8B. The surface 3a of said buffer layer 3 is then locally scratched with a scratching tool 80 at locations intended for barrier structures, thus forming a disturbance pattern 81 on or in the buffer layer 3, see FIG. 8C. This is followed by depositing material, here components for YBCO, on the patterned surface 3a, see FIG. 8D. Above the disturbance pattern 81, material growth results in non-superconducting (or poorly superconducting) material in a space 65 forming a barrier structure 5, and lateral of the disturbance pattern 81, superconducting material, here YBCO, of the superconductor layer 4 grows.

Note that in the tape type superconductor 1, the elemental composition of the material of the superconductor layer 4 and the barrier structure 5 are identical here, but the disturbance pattern 81 causes a different phase composition and/or a different crystallinity, resulting in different characteristics with respect to superconductivity.

It should be noted that instead of scratching (or otherwise disturbing) the surface 3a of the buffer layer 3, also the polished surface 2a of the substrate tape 2 may be scratched (or otherwise disturbed). The buffer layer (or layers) deposited on top can carry on this disturbance pattern to the surface 3a of the buffer layer 3 then, also resulting in a superconductor layer 4 and barrier structures 5 upon material deposition.

In the fourth variant of a method for producing a tape type superconductor shown in FIG. 9A-9C, first a semi-finished product with a substrate tape 2, at least one continuous buffer layer 3 and a continuous superconductor layer 4, here of YBCO, is produced (see also FIGS. 6A-6C above), compare FIG. 9A. Then at locations intended for barrier structures, the material of the superconductor layer 4 is locally heated with a heating device 90, compare FIG. 9B. In a region 91, the superconducting material of the superconductor layer 4 degrades and becomes non-superconductive, for example by a non-reversible phase transition. This results in a barrier structure 5 of non-superconducting material in the corresponding space 65 in the tape type superconductor 1, compare FIG. 9C.

In the illustrated variant, the elemental composition of the originally superconducting material of the superconductor layer 4 does not change upon the heat treatment. However, in another variant, very strong heating may lead to a thermolysis, with elements evaporating into the surrounding; in this case the elemental composition will change in the space 65 or the barrier structure 5 as compared to the superconductor layer 4.

In summary, the invention proposes a tape type superconductor with a plurality of barrier structures within its superconductor layer. The barrier structures are much shorter than the total length of the tape type superconductor, and the barrier structures are arranged subsequent in longitudinal direction, to which they are parallel. At a particular position in width direction, numerous barrier structures, typically 10 or more, often 100 or more, are arranged subsequently in longitudinal direction, but separated from each other by superconducting intermediate regions. The barrier structures are arranged at at least one position in width direction, but there may be a plurality of positions in width direction over which the barrier structures are distributed. The barrier structures may be distributed in a pattern periodic in longitudinal direction, or may be arranged in a random pattern. The barrier structures are non-superconducting or worse superconducting as compared to the superconductor layer. The separated barrier structures allow for a decoupling of regions in the superconductor layer, but all regions of the superconductor layer are still interconnected superconductingly. This reduces unwanted induced magnetization, without a substantial reduction of the critical current. Inventive tape type superconductors may be used in spools, magnet coils, in particular for NMR magnets, for motors or generators, transformers, fault current limiters or cables, for example.

### LIST OF REFERENCE SIGNS

1 tape type superconductor
2 substrate tape
2a surface (substrate tape)
2 buffer layer
3a surface (buffer layer)
4 superconductor layer
5, 5a, 5b barrier structures
6a-6e positions
7 intermediate region
8 flat side (substrate tape)
60 laser beam
61 laser device
62 laser spot
63 groove
64 surface (combined superconductor layer and barrier structure)
65 space
70 beam of ions
71 ion gun
72 region (affected by ions)
80 scratching tool
81 disturbance pattern
90 heating device
91 region (affected by heating)
ABD average barrier density
HD height direction
H_{SL} height of superconductor layer
L_{BS} length of barrier structure
L_{BS}^{long} length of longest barrier structure
L_{BS}^{short} length of shortest barrier structure
LD longitudinal direction
L_{IR} length of intermediate region
L_{TTS} length of tape type superconductor
P period
WD width direction
W_{BS} width of a barrier structure
W_{SL} width of superconductor layer

What is claimed is:

1. A tape type superconductor, extending along a longitudinal direction, and comprising:
a substrate tape,
at least one buffer layer,
a superconductor layer,
wherein the superconductor layer has a width W_{SL} in a width direction, that is perpendicular to the longitudinal direction and is parallel to a flat side of the substrate tape,
wherein the tape type superconductor has a length L_{TTS} in the longitudinal direction, and
a plurality of elongated barrier structures which are oriented in parallel with the longitudinal direction,
wherein a respective one of the barrier structures has a length L_{BS} in the longitudinal direction,
with L_{BS}≥0.20*W_{SL} and L_{BS}≤0.20*L_{TTS},
wherein the barrier structures are arranged distributed along the longitudinal direction, and
wherein the barrier structures are located at least partially in the superconductor layer and impede a superconducting current flow in the width direction across a respective barrier structure.

2. A tape type superconductor according to claim 1, wherein the superconductor layer has a complete height H_{SL}, and a respective one of the barrier structures extends across the complete height H_{SL} of the superconductor layer in a height direction,
wherein the height direction extends perpendicularly to the longitudinal direction and extends perpendicularly to the flat side of the substrate tape.

3. A tape type superconductor according to claim 1, wherein the barrier structures are non-superconducting or exhibit a critical current density j_{c}^{BS} in the width direction which is less than 1/100 of a critical current density j_{c}^{SL} in the width direction of a superconducting material of the superconductor layer.

4. A tape type superconductor according to claim 1, wherein the barrier structures are spaces filled with a non-superconducting material of a chemical composition that differs from a chemical composition of a superconducting material of the superconductor layer.

5. A tape type superconductor according to claim 4, wherein the spaces are filled with a non-superconducting metal.

6. A tape type superconductor according to claim 1, wherein the barrier structures have a chemical composition that is the same as a chemical composition of a superconducting material of the superconductor layer, and wherein the chemical compositions of the barrier structures versus the superconducting material exhibit deviations in phase composition and/or exhibit disturbances in crystalline structure.

7. A tape type superconductor according to claim 1, wherein at least 80% of the length L_{TTS} of the tape type superconductor is overlapped by the barrier structures.

8. A tape type superconductor according to claim 1, wherein at least 80% of the length L_{TTS} of the tape type superconductor is overlapped by at least n of the barrier structures which are sequent in the width direction, with n≥2.

9. A tape type superconductor according to claim 1, wherein, for an average barrier density ABD, which is defined as a local barrier density of the tape type superconductor averaged along the complete length L_{TTS}, with the local barrier density being the number of barrier structures intersected by a cross section of the tape type superconductor perpendicular to the longitudinal direction at a local position in longitudinal direction:
ABD≥0.80.

10. A tape type superconductor according to claim 9, wherein:
ABD≤2.5 and W_{SL}/(2*ABD)≤L_{BS}, and/or
ABD≤250 and L_{BS}≤(50/ABD)*W_{SL}, and/or
ABD≤5 and W_{SL}/ABD≤L_{BS}, and/or
ABS≤125 and L_{BS}≤(25/ABD)*W_{SL}.

11. A tape type superconductor according to claim 9, wherein the barrier structures are arranged distributed over at least m different positions in the width direction, with m>2*ABD or m>3*ABD.

12. A tape type superconductor according to claim 11, wherein on average over the length L_{TTS}, the barrier structures are at least approximately equally distributed over the at least m different positions in the width direction.

13. A tape type superconductor according to claim 1, wherein a superconducting material of the superconductor layer is a high temperature superconductor.

14. A tape type superconductor according to claim 13, wherein the high temperature superconductor is REBCO or BiSCCO or MgB₂.

15. A tape type superconductor according to claim 1, wherein between respective two barrier structures subsequent in width direction there is an intermediate region belonging to the superconductive layer, wherein the intermediate region has a length L_{IR} in longitudinal direction, and wherein L_{IR}≤W_{SL}.

16. A tape type superconductor according to claim 1, wherein between respective two barrier structures subsequent in width direction there is an intermediate region belonging to the superconductive layer, wherein the intermediate region has a length L_{IR} in longitudinal direction, and wherein L_{IR}≥0.25*W_{SL}/(m+1) and L_{IR}≤4*W_{SL}/(m+1), with m: number of positions in width direction over which the barrier structures are distributed.

17. Method for producing a tape type superconductor according to claim 4, comprising:
depositing at least one continuous one of the buffer layers on the substrate tape,
depositing superconducting material forming a continuous superconductor layer on the at least one continuous buffer layer,
at locations predetermined for the barrier structures, locally removing the superconducting material of the continuous superconductor layer, to form grooves reaching at least to the at least one continuous buffer layer, and
filling the grooves with a non-superconducting material of a chemical composition that differs from the chemical composition of the superconducting material of the superconductor layer.

18. Method according to claim 15, wherein the superconducting material is locally removed by laser etching, to form grooves reaching at least to the at least one continuous buffer layer.

19. Method for producing a tape type superconductor according to claim 4, comprising:
depositing at least one continuous one of the buffer layers on the substrate tape,
depositing superconducting material forming a continuous superconductor layer on the at least one continuous buffer layer,
at locations predetermined for the barrier structures, locally converting the superconducting material of the continuous superconductor layer into the non-superconducting material of the chemical composition that differs from the chemical composition of the superconducting material of the superconductor layer.

20. Method according to claim 19, wherein the superconducting material is locally converted by ion bombardment.

21. Method for producing a tape type superconductor according to claim 6, wherein:
at locations predetermined for barrier structures,
a) locally disturbing a surface of a buffer layer deposited on the substrate tape, to form a disturbance pattern, or
b) locally disturbing a surface of a substrate tape, to form a disturbance pattern, and depositing a buffer layer on the substrate tape,
and depositing material on the buffer layer such that the superconducting material of the superconductor layer forms everywhere on the buffer layer except on the disturbance pattern.

22. Method according to claim 21, wherein the surface of the buffer layer or the surface of the substrate tape is locally disturbed by scratching or laser etching.

23. Method for producing a tape type superconductor according to claim 6, comprising:
depositing at least one continuous one of the buffer layers on the substrate tape,
depositing superconducting material forming a continuous superconductor layer on the at least one continuous buffer layer,
at locations predetermined for the barrier structures, locally treating the superconducting material of the continuous superconductor layer to impose a new phase composition and/or crystalline structure disturbances without changing a chemical composition of the superconducting material.

24. Method for producing the tape type superconductor according to claim 23, wherein the local treating of the superconducting material comprises local heating of the superconducting material.
